(19) United States
(12) Patent Application Publication
(10) Pub. No.: US 2026/0182296 A1
(43) Pub. Date: Jun. 25, 2026

(54) SYSTEM AND METHOD FOR REPAIRING VACANCIES ON A SUBSTRATE

(71) Applicant: RAYLEIGH VISION INTELLIGENCE CO., LTD., Hsinchu City (TW)

(72) Inventor: Ning-Yuan LYU, Hsinchu City (TW)

(21) Appl. No.: 19/432,534

(22) Filed: Dec. 24, 2025

(30) Foreign Application Priority Data
Dec. 24, 2024 (TW) 113150417

(51) Int. Cl. H10P 72/00; H10P 72/50

(52) U.S. Cl. CPC H10P 72/0442; H10P 72/0606; H10P 72/53

(57) ABSTRACT

A system for repairing vacancies on a substrate is provided. The system comprises a transfer apparatus, an image recognition module, and a computing processor. The transfer apparatus is configured to transfer at least one first chip on a first substrate into a vacancy on a second substrate. The image recognition module respectively inspects and obtains the first position data of the at least one first chip on the first substrate and the second position data of at least one second chip on the second substrate. The computing processor inputs the first position data and the second position data into a prediction machine model and obtains an optimal relative displacement, wherein the transfer apparatus generates a movement with the optimal relative displacement between the second substrate and the first substrate so as to proceed the transfer of the at least one first chip.

### CROSS-REFERENCE TO RELATED APPLICATION

This application claims priority from Taiwan Patent Application No. 113150417 filed on Dec. 24, 2024, which are hereby incorporated herein by reference in its entirety.

### BACKGROUND OF THE INVENTION

### Field of the Invention

The present disclosure relates to a system and method for repairing vacancies on a substrate, in particular to a system and method that uses machine learning models to repair vacancies on target substrates where chips are missing.

### Description of Related Art

Mass transfer is a key technology for achieving the mass production of micro-LED (Micro LED) displays. Millions or even tens of millions of micro-scale RGB chips on an original substrate are transferred in batches to a display substrate that includes the driving circuit through mass transfer technology. After being exposed to a laser beam, the release layer material absorbs the emitted energy, which weakens the adhesion between the chips and the temporary or carrier substrate. As a result, when the chips are detached from the release layer, they are transferred to the target substrate, completing the transfer process.

However, after mass transfer, a considerable number of chip vacancies may appear on the target substrate (or the driving substrate of a display). Therefore, repair equipment is used to implant chips individually into these vacancies. To repair the vacancies, the repair equipment will move the temporary substrate or the target substrate to align the chips on the temporary substrate with the vacancies on the target substrate, and then complete the chip transfer using a laser beam.

In fact, vacancies are irregularly distributed on the target substrate and vacancies are accordingly formed on the temporary substrate after chip transfer. Moreover, some chips have been identified as abnormal or defective so that they cannot be implanted on the target substrate, resulting in reduced transfer efficiency.

### SUMMARY OF THE INVENTION

In view of deficiencies in conventional systems for repairing vacancies on substrates, the present disclosure provides a device for repairing vacancies on a substrate, designed for high transfer efficiency.

In one aspect of the present disclosure, a system for repairing vacancies on a substrate is provided. The system comprises a transfer apparatus configured to transfer at least one first chip from a first substrate to at least one vacancy on a second substrate; an image recognition module configured to respectively inspect and obtain first position data of the at least one first chip on the first substrate and second position data of at least one second chip on the second substrate; and a computation processing module configured to input the first position data and the second position data into a predictive machine model to obtain an optimal relative displacement; wherein the transfer apparatus generates a motion between the second substrate and the first substrate based on the optimal relative displacement to perform a transfer of the at least one first chip.

In yet another aspect of the present disclosure, the optimal relative displacement is obtained by adjusting parameters in the predictive machine model to minimize a loss value.

In another aspect of the present disclosure, after the transfer of the at least one first chip, the transfer apparatus counts a number of remaining vacancies on the second substrate.

In another aspect of the present disclosure, if the number of the remaining vacancies is not zero, the first position data and the second position data are updated and another optimal relative displacement is calculated for a next transfer of chips.

In another aspect of the present disclosure, an architecture of the predictive machine model includes: a repair platform simulator generating first virtual position data and second virtual position data; a platform displacement prediction model having inputs of the first virtual position data and the second virtual position data to calculate a plurality of scores of platform displacement, obtaining an optimal virtual relative displacement corresponding to a highest score which is selected from the scores, providing the optimal virtual relative displacement to the repair platform simulator to generate simulated movement and simulate a transfer of chips, and output a transfer count; and a loss function model updating parameters of the platform displacement prediction model based on the transfer count and the scores of the platform displacement.

In another aspect of the present disclosure, a method for repairing vacancies on a substrate is provided. The method comprises inspecting a first substrate to obtain a first position data for at least one first chip and inspecting a second substrate to obtain a second position data for at least one second chip; inputting the first position data and the second position data into a predictive machine model to obtain an optimal relative displacement; generating a motion between the second substrate and the first substrate based on the optimal relative displacement; and transferring the at least one first chip to at least one vacancy on the second substrate.

In yet another aspect of the present disclosure, the step of obtaining the optimal relative displacement further comprises adjusting parameters of the predictive machine model to minimize a loss value, thereby obtaining the optimal relative displacement.

In yet another aspect of the present disclosure, the method further comprises calculating a number of remaining vacancies on the second substrate after a transfer of the at least one first chip is complete.

In yet another aspect of the present disclosure, an architecture of the predictive machine model is generated by the following steps: generating first virtual position data and second virtual position data; inputting the first virtual position data and the second virtual position data to calculate a plurality of scores of platform displacement; obtaining an optimal virtual relative displacement corresponding to a highest score which is selected from the scores; using the optimal virtual relative displacement to simulate a motion between the second substrate and the first substrate and a transfer of chips, and output a transfer count; and updating parameters of the predictive machine model based on the transfer count and the scores of the platform displacement.

By applying the optimal relative displacement, the system shortens each relative movement between the first (temporary) substrate and the second (target) substrate and maximizes the number of chips on the first substrate that can be aligned with the vacancies on the second substrate, thereby increasing the transfer efficiency of the repair equipment.

### BRIEF DESCRIPTION OF THE DRAWINGS

In order to sufficiently understand the essence, advantages and the preferred embodiments of the present invention, the following detailed description will be more clearly understood by referring to the accompanying drawings.

FIG. 1 is a block diagram illustrating the configuration of a system for repairing vacancies on a substrate according to an embodiment of the present disclosure.

FIGS. 2A and 2B are schematic diagrams illustrating the chip distribution and status on a carrier substrate and a target substrate according to an embodiment of the present disclosure.

FIGS. 2C and 2D are schematic diagrams illustrating the position data of the chip distribution and status on the carrier substrate and the target substrate shown in FIGS. 2A and 2B.

FIG. 3 is a schematic diagram illustrating the relative displacement between the carrier substrate and the target substrate.

FIG. 4 is a schematic diagram illustrating the architecture of a machine learning model that can plan repair paths.

FIG. 5 is a flowchart illustrating the process of training a predictive machine model to plan repair paths.

FIG. 6 is a schematic diagram illustrating the architecture of a platform displacement prediction model.

FIG. 7 is a flowchart illustrating the process of executing the predictive machine model for repair.

FIGS. 8A and 8B are schematic diagrams illustrating the chip distribution on the carrier substrate and the target substrate according to one embodiment of the present disclosure.

FIGS. 8C to 8F are schematic diagrams illustrating four possible relative displacements between the carrier substrate and the target substrate.

### DETAILED DESCRIPTION OF THE INVENTION

The following description shows the preferred embodiments of the present invention.

The present invention is described below by referring to the embodiments and the figures. Thus, the present invention is not intended to be limited to the embodiments shown but is to be accorded the principles disclosed herein. Furthermore, that various modifications or changes in light thereof will be suggested to persons skilled in the art and are to be included within the spirit and purview of this application and scope of the appended claims.

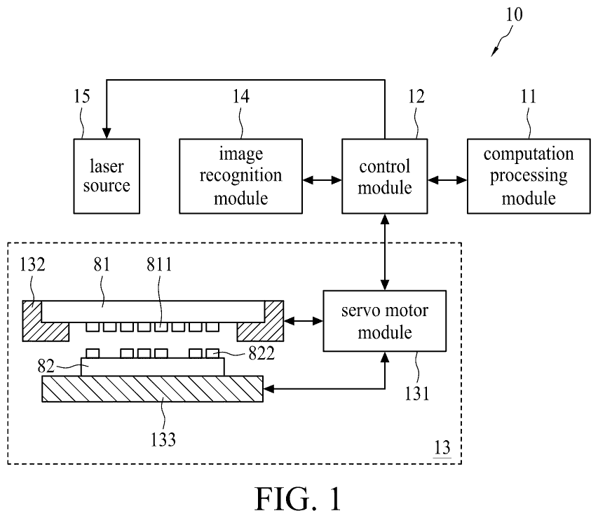

FIG. 1 is a block diagram illustrating the configuration of a system for repairing vacancies on a substrate. The system 10 of this embodiment comprises a computation processing module 11, a control module 12, a transfer device 13, an image recognition module 14, and a laser source 15. In this embodiment, the transfer device 13 comprises a servo motor module 131, a carrier platform 132, and a target platform 133. The servo motor module 131 can generate the relative movement of the carrier platform 132 and the target platform 133 in a horizontal plane, allowing specific positions of the carrier substrate 81 (or first substrate) on the carrier platform 132 to align with specific positions of the target substrate 82 (or second substrate) on the target platform 133.

Thus, one or more chips 811 (or first chips) on the carrier substrate 81 can be respectively implanted into the empty positions between chips 822 (or second chips) on the target substrate 82 after the release layer (not shown) is irradiated by the laser beam from the laser source 15.

The image recognition module 14 includes an image capture unit and a judgment unit, which can separately inspect the distribution and status (normal or defective) of chips (811, 822) on the carrier substrate 81 and the target substrate 82. The first position data of chips 811 on the carrier substrate 81 and the second position data of chips 822 on the target substrate 82 are accordingly obtained. The first and second position data include the locations of the chips and the vacancies, as well as the status of the chips. The servo motor module 131, based on the control signals generated by the control unit 12, can move the carrier platform 132 and the target platform 133 separately to achieve a better or optimal relative displacement. This relative displacement is calculated and output by the computational processing module 11, which uses the first and second position data as inputs to a predictive machine model. By adjusting the parameters of the predictive machine model to minimize the loss value, the optimal relative displacement vector is accordingly obtained. The training and learning of the predictive machine model, as well as the computational process during the transfer of chips by the system 10, will be discussed in subsequent paragraphs.

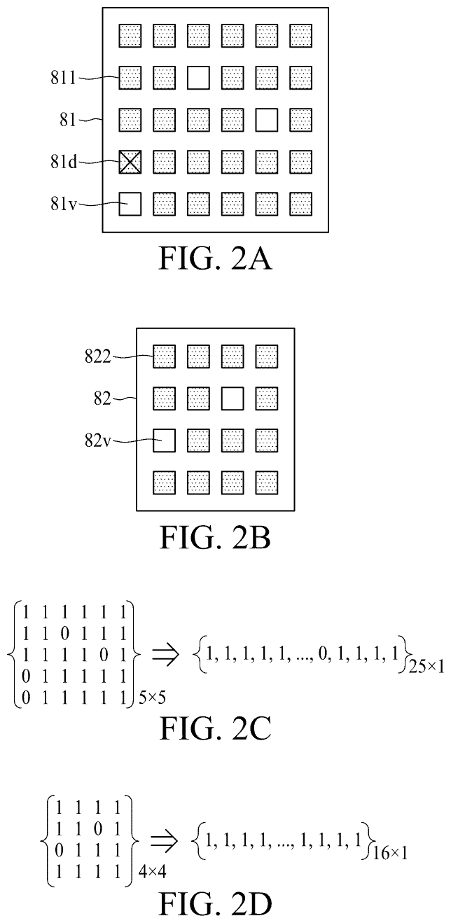

FIGS. 2A and 2B illustrate the chip distribution and status on the carrier substrate and the target substrate according to one embodiment of the present disclosure. After inspection by the image recognition module 14, it is found that the carrier substrate 81 has chips 811, defective chips 81d, and vacancies 81v, while the target substrate 82 has chips 822 and vacancies 82v. Based on these image judgment results, the first and second position data can be converted into arrays required by the computation processing module 11. Referring to FIG. 2C, the first position data can be represented as a 5×5 matrix, which is further converted into a 25×1 array S1. Similarly, the second position data can be represented as a 4×4 matrix, which is further converted into a 16×1 array S2. These arrays S1 and S2 are only illustrative, and, however, in practical applications, the number of chips on the carrier substrate and the target substrate is much larger.

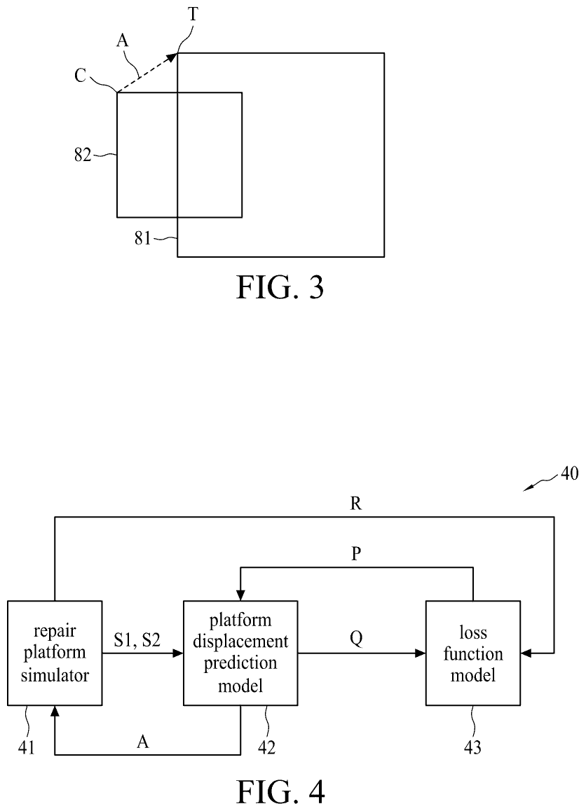

FIG. 3 is a schematic diagram illustrating the relative displacement between the carrier substrate and the target substrate. For example, taking the upper left corner of the carrier substrate 81 as reference point C and the upper left corner of the target substrate 82 as reference point T, the relative displacement A can be represented as the displacement of reference point C relative to reference point T, such as a displacement vector {Ax, Ay} indicating the direction and magnitude of the movement. The direction and magnitude of the relative displacement A in the figure are only illustrative and do not limit the scope of the present application.

The training and learning framework for the prediction machine model is shown in FIG. 4, allowing it to be applied in the aforementioned system 10 to plan the optimal repair path. The framework 40 includes a repair platform simulator 41, a platform displacement prediction model 42, and a loss function model 43. The repair platform simulator 41 includes a virtual carrier platform, a virtual target platform, and a virtual laser source. During the computation, the repair platform simulator 41 generates virtual arrays (S1, S2) (see FIGS. 2C and 2D) and inputs them into the platform displacement prediction model 42 to obtain an optimal relative displacement A. The virtual carrier platform and the virtual target platform in the repair platform simulator 41 then simulate movement based on the optimal relative displacement A, and the virtual laser source transfers the chips from the virtual carrier platform to the vacancies on the target platform. After the virtual laser source has sequentially completed the chip transfer, the repair platform simulator 41 outputs the number of transferred chips R to the loss function model 43. The loss function model 43 updates the parameters P in the platform displacement prediction model 42 based on the number R and the platform displacement score Q. The platform displacement prediction model 42 then uses the updated parameters P to calculate a relative displacement A for the next round, and selects the relative displacement A corresponding to the highest platform displacement score Q (the optimal one) to output to the repair platform simulator 41.

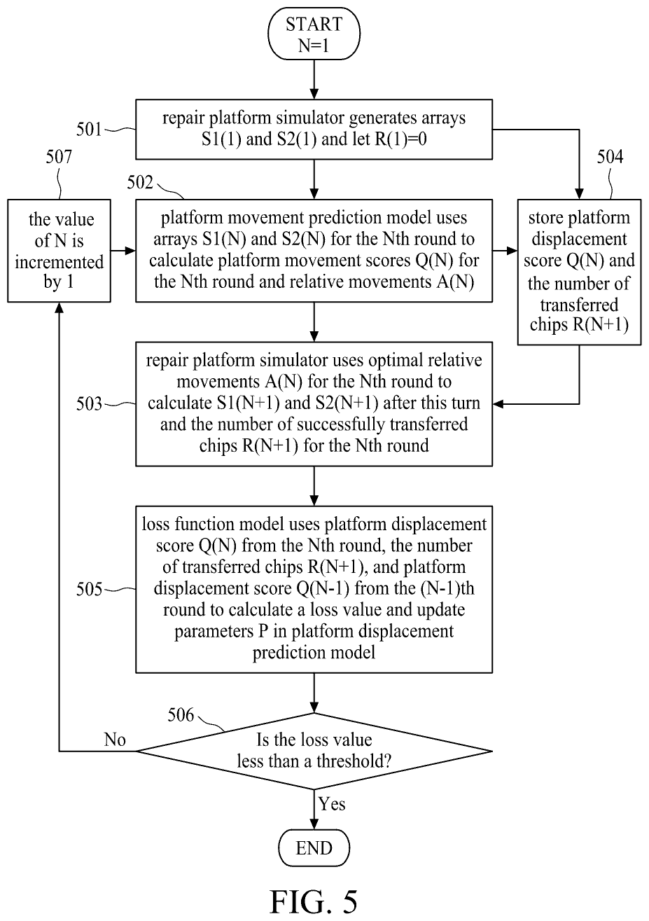

FIG. 5 is a flowchart depicting the process of training a predictive machine model for planning repair paths. As shown in step 501, at the beginning of the first round of training and learning (i.e., N=1), the repair platform simulator 41 generates virtual initial arrays S1(1) and S2(1) representing the first and second position data, respectively, and sets the number of transferred chips R(1) to 0. In step 502, the platform movement prediction model 42 receives the initial arrays S1(1) and S2(1) to calculate multiple platform movement scores Q(1) (or Q(N) for the Nth round) and their corresponding relative movements A(1) (or A(N)). In step 503, the repair platform simulator 41 selects the higher platform movement score Q(1) (or Q(N)) and simulates the movement between the carrier substrate and the target substrate using the relative movement A(1) (or A(N)) corresponding to the highest score, thereby completing the chip transfer. After the first round (or the Nth round) of transfer, the distributions of chips on the carrier substrate and the target substrate change. The repair platform simulator 41 then updates the arrays representing the first and second position data to S1(2) (or S1(N+1)) and S2(2) (or S2(N+1)), respectively, and generates the number of successfully transferred chips R(2) (or R(N+1)).

The platform displacement score Q(1) and the number of transferred chips R(2) are stored in memory or a storage device, as shown in step 504. The loss function model 43 uses the platform displacement score Q(1), the number R(2), and the platform displacement score Q(2) to calculate the loss value, and further minimizes the loss value to update the parameters P in the platform displacement prediction model 42. When the loss value is less than a threshold, the training and learning process ends, as shown in step 506. If the loss value is not less than the threshold, as shown in step 507, the value of N is incremented by 1, and the next round of chip transfer simulation is performed until the loss value is less than the threshold, at which point the training ends.

Similarly, after updating the parameters P, the platform displacement prediction model 42 calculates the platform displacement score Q(N) and the corresponding optimal relative displacement A(N) for the current Nth round based on the arrays S1(N) and S2(N), as shown in step 502. In step 503, the repair platform simulator 41 calculates the S1(N+1) and S2(N+1) after the Nth round of transfer based on the optimal relative displacement A(N), and also calculates the number of successfully transferred chips R(N+1). The loss function model 43 then uses the platform displacement score Q(N) from the Nth round, the number of successfully transferred chips R(N+1), and the platform displacement score Q(N−1) from the previous round to calculate the loss value, and further minimizes the loss value so as to update the parameters P in the platform displacement prediction model 42, as shown in step 505.

The formula for calculating the loss value is expressed as follows:

$$Loss = {[ R ( N ) + γ Q ( N ) - Q ( N - 1 ) ]}^{2} , γ = 0.95 ;$$

(This formula and its coefficients are illustrative and do not limit the scope of this application).

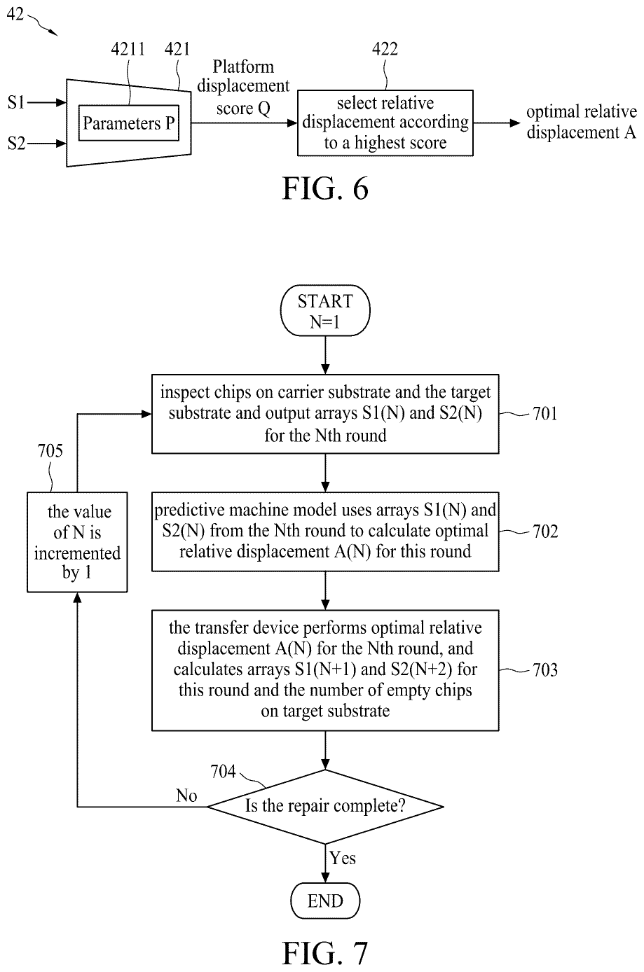

FIG. 6 illustrates a schematic diagram of the platform displacement prediction model. The virtual initial arrays S1 and S2, representing the first position data (chips on the carrier substrate) and the second position data (chips on the target substrate), are input into the machine learning model 421 of the platform displacement prediction model 42. The model calculates the platform displacement score Q for each round based on the parameters P 4211 that are updated in each round. The function block 422 then retrieves the relative displacement corresponding to the highest score, and finally outputs the optimal relative displacement A.

FIG. 7 illustrates a flowchart of the process for executing the predictive machine model to perform repairs. As shown in step 701, during the Nth chip transfer (if it is the first round, then N=1), the image recognition module 14 inspects the chips on the carrier substrate and the target substrate, and outputs the array S1(N) representing the first position data of the chips on the carrier substrate and the array S2(N) representing the second position data of the chips on the target substrate. The predictive machine model uses the arrays S1(N) and S2(N) from the Nth round to calculate the optimal relative displacement A(N) for that round, as shown in step 702. In step 703, the transfer device performs the optimal relative displacement A(N) for the Nth round, and calculates the arrays S1(N+1) and S2(N+2) representing the positions of the chips on the carrier substrate and the target substrate after the transfer. It also calculates the number of empty chips (i.e., vacancies) on the target substrate. If the number of missing chips is zero or less than a predetermined value, the repair or implantation of the chips is considered complete, as shown in step 704, and the repair process for the target substrate is terminated. If the number of empty chips is not zero or exceeds the predetermined value, the process moves to step 705, where the value of N is incremented by one, and the next round of repair is performed by repeating steps 702 to 703 until the chip repair or implantation is confirmed to be complete.

### [Computations for Training the Predictive Machine Model]

The first set of position data for the chip distribution on the carrier substrate is represented by array S1 with a H₁×W₁ matrix, and the initial array of the second set of position data for the chip distribution on the target substrate is represented by array S2. Arrays S1 and S2 can be expressed as follows:

$$S 1 = [ {x}_{1} , {x}_{2} ... {X}_{{W}_{1} + 1} ... {X}_{2 {W}_{1}} ... {X}_{{N}_{1} - 1} , {X}_{{N}_{1}} ] ;$$

$$S 2 = [ {x}_{{N}_{1} + 1} , {x}_{{N}_{1} + 2} ... ... ... ... ... ... {x}_{{N}_{1} + {N}_{2}} ] ;$$

where each of x₁-x₂ is either 0 or 1; each of x_{N}_{₁}₊₁−x_{N}_{₁}_{+N}_{₂} is either 0 or 1, indicating the presence or absence of a chip at a specific position; H₁×W₁=N₁; H₂×W₂=N₂.

Referring to FIG. 6, the machine learning model 421 includes a function with parameters P. The function takes arrays S1 and S2 as inputs and produces multiple function values. Each value represents a platform displacement score Q corresponding to a relative displacement. If there are L possible relative displacements A, the function outputs L platform displacement scores Q, which are q₁ to q_{L}.

$${q}_{1} = {f}_{1} ( {S}_{1} , {S}_{2} ; P ) ;$$

$${q}_{2} = {f}_{2} ( {S}_{1} , {S}_{2} ; P ) ;$$

$$...$$

$${q}_{L} = {f}_{L} ( {S}_{1} , {S}_{2} ; P ) ;$$

or combined as:

$$Q = F ( {S}_{1} , {S}_{2} ; P ) ;$$

where Q is the set of q₁ to q_{L}, and F is the set of functions f₁ to f_{L}; parameter set P={pᵢ}, which all parameters pᵢ are initialized with random values.

The highest score is selected from q₁ to q_{L} within the platform displacement scores Q, and is expressed using MAX(F(S₁,S₂; P)). The relative displacement A corresponding to the highest score is the optimal relative displacement A*. The virtual carrier platform and the virtual target platform in the repair platform simulator 41 will generate simulated movements based on the optimal relative displacement A*. This results in the number of transferred chips R. For the next round of chip transfer, the optimal relative displacement A* from the previous round is used as A′, and the arrays S1 and S2 are updated to S1′ and S2′, respectively. The platform displacement scores Q from the previous round are also updated to Q′.

Substituting S1′, S2′, A′, and Q′ updated during the previous round (or iteration) and the current S1, S2, A*, and Q in the current round, the parameters pᵢ of P are calculated and updated using the following formula:

$${p}_{i} + α [ R + γ {q}_{{A}^{*}} ( {S}_{1} , {S}_{2} ; P ) - {q}_{{A}^{′}} ( {S}_{1}^{′} , {S}_{2}^{′} ; P ) ] \frac{\partial {q}_{{A}^{′}} ( {S}_{1}^{′} , {S}_{2}^{′} ; P )}{\partial {p}_{i}} ;$$

where α=0.05; γ=0.95; if the calculation of q_{A′} is performed using a neural network,

$$\frac{\partial {q}_{{A}^{′}} ( {S}_{1}^{′} , {S}_{2}^{′} ; P )}{\partial {p}_{i}}$$

can be achieved using current open-source neural network development platforms (such as TensorFlow, PyTorch, or MxNet).

### [Example of Generating a Predictive Machine Model for Optimal Relative Displacement]

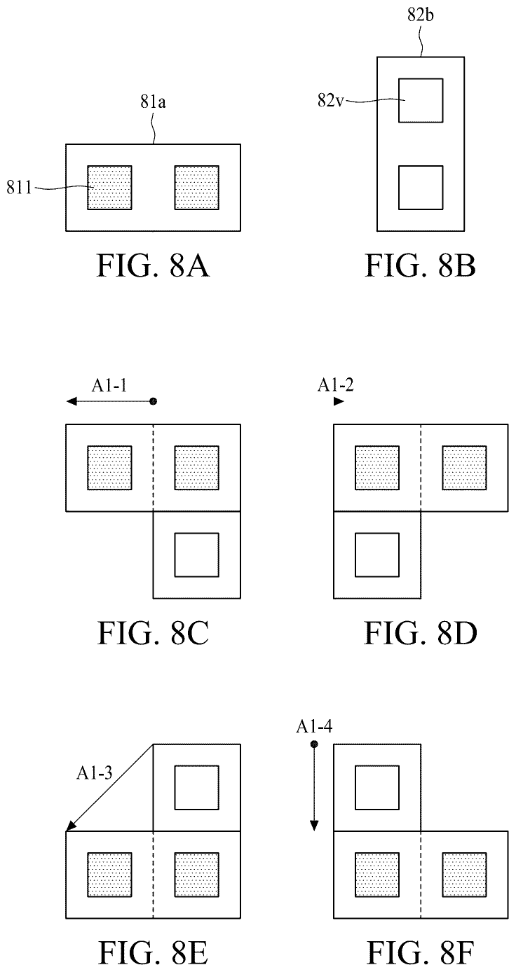

FIGS. 8A and 8B illustrate the chip distribution on the carrier substrate and the target substrate according to one embodiment of the present disclosure. The initial array S1(1) of the first position data of the chip distribution on the carrier substrate 81a, and the initial array S2(1) of the second position data of the chip distribution on the target substrate 82b are represented as follows:

$${S}_{1} = [ {x}_{1} {x}_{2} ] = [ 11 ] , {H}_{1} = 1 , {W}_{1} = 2 , {N}_{1} = 2 ;$$

$${S}_{2} = [ {x}_{3} {x}_{4} ] = [ 00 ] , {H}_{2} = 2 , {W}_{2} = 1 , {N}_{2} = 2.$$

The parameter values pᵢ=wₘₙ, 1≤m≤4, 1≤n≤4; pᵢ=bₗ, 1≤l≤4. Two sets of parameter values are as follows:

$$[ {w}_{11} {w}_{12} {w}_{13} {w}_{14} {w}_{21} {w}_{22} {w}_{23} {w}_{24} {w}_{31} {w}_{32} {w}_{33} {w}_{34} {w}_{41} {w}_{42} {w}_{43} {w}_{44} ] = [ 0.323 - 0.319 0.313 0.165 - 1.489 1.107 - 0.7408 - 0.526 0.648 0.245 - 1.661 - 0.526 2.761 0.641 0.294 - 2.469 ] ; and$$

$$[ {b}_{1} {b}_{2} {b}_{3} {b}_{4} ] = [ 0000 ] .$$

The platform displacement score Q can be calculated using the following formula:

$$Q = [ {q}_{1} {q}_{2} {q}_{3} {q}_{4} ] = [ {w}_{11} {w}_{12} {w}_{13} {w}_{14} {w}_{21} {w}_{22} {w}_{23} {w}_{24} {w}_{31} {w}_{32} {w}_{33} {w}_{34} {w}_{41} {w}_{42} {w}_{43} {w}_{44} ] \times [ {x}_{1} {x}_{2} {x}_{3} {x}_{4} ] + [ {b}_{1} {b}_{2} {b}_{3} {b}_{4} ] = [ 0.004 - 0.382 0.893 3.402 ] .$$

Referring to FIGS. 8C to 8F, they show four possible relative displacements between the carrier substrate and the target substrate. The first relative displacement A1-1 in the set A(1) corresponding to FIG. 8C is (−1, 0); the second relative displacement A1-2 in the set A(1) corresponding to FIG. 8D is (0, 0); the third relative displacement A1-3 in the set A(1) corresponding to FIG. 8E is (−1, −1); and the fourth relative displacement A1-4 in the set A(1) corresponding to FIG. 8F is (0, −1).

The maximum value in Q=[0.004 −0.382 0.893 3.402] is 3.402, which corresponds to the 4th relative displacement A1-4, so the optimal relative displacement is (0, −1). For the simulation of the next round of chip transfers, let A′=(0, −1), S₁′=[1 1], S₂′=[0 0], and Q′=[0.004 −0.382 0.893 3.402]. At the start of the second round of chip transfer simulation, arrays S1(2) and S2(2) are represented as S₁=[0 1], S₂=[0 1], thus the number of successfully transferred chips R=1.

Recompute the platform displacement scores for the second round, resulting in Q=[0.323 −0.319 0.313 0.165 −1.489 1.107 −0.7408 −0.526 0.648 0.245 −1.661 −0.526 2.761 0.641 0.294 −2.469]×[0 1 0 1]+[0 0 0 0]=[0.155 2.957 −0.281 −1.828]. The maximum value q₂ in newly updated Q=[0.155 2.957 −0.281 −1.828] is 2.957, corresponding to the 2nd displacement, which is the 2nd relative displacement A1-2, so the optimal relative displacement A* is (0, 0). Therefore, the carrier platform and the target platform complete the relative movement and subsequent chip transfer with the optimal relative displacement (0, 0).

The parameter P (={pᵢ}) is updated as follows:

$${p}_{i} + α [ R + γ {q}_{{A}^{*}} ( {S}_{1} , {S}_{2} ; P ) - {q}_{{A}^{′}} ( {S}_{1}^{′} , {S}_{2}^{′} ; P ) ] \frac{\partial {q}_{{A}^{′}} ( {S}_{1}^{′} , {S}_{2}^{′} ; P )}{\partial {p}_{i}} ;$$

$${q}_{{A}^{*}} ( {S}_{1} , {S}_{2} ; P ) = {q}_{2} ( {S}_{1} , {S}_{2} ; P ) = 2.957 ;$$

$${q}_{{A}^{′}} ( {S}_{1}^{′} , {S}_{2}^{′} ; P ) = {q}_{4} ( {S}_{1}^{′} , {S}_{2}^{′} ; P ) = 3.402 ;$$

$$α = 0.05 , γ = 0.95 , R = 1.$$

When the parameter pᵢ is w₄ₙ, the original parameter w₄ₙ will be [2.7610.641 0.294 −2.469]. The parameter P is accordingly adjusted according to the aforementioned calculation formula to:

$$[ 2.761 0.641 0.294 - 2.469 ] + 0.05 \times ( 1 + 0.95 \times 2.957 - 3.402 ) \times [ 1100 ] = [ 2.781 0.661 0.294 - 2.469 ] .$$

Furthermore, when the parameter pᵢ is b₄, then

$$\frac{\partial {q}_{{A}^{′}} ( {S}_{1}^{′} , {S}_{2}^{′} ; P )}{\partial {p}_{i}} = \frac{\partial ( {\sum }_{j = 1}^{4} {w}_{4 j} {x}_{j} + {b}_{4} )}{\partial {b}_{4}} = 1.$$

Therefore, since the original b₄ is zero, the new b₄ is updated as b₄=0+0.05×(1+0.95×2.957 −3.402)×1=0.02.

For other parameters pᵢ=w_{wn} and bₘ, since

$$\frac{\partial {q}_{{A}^{′}} ( {S}_{1}^{′} , {S}_{2}^{′} ; P )}{\partial {p}_{i}} = 0 ,$$

they both are not updated. The updated parameters P={pᵢ}={wₘₙ; bₘ} are the values represented in the following arrays:

$${w}_{mn} = [ 0.323 - 0.319 0.313 0.165 - 1.489 1.107 - 0.7408 - 0.526 0.648 0.245 - 1.661 - 0.526 2.781 0.661 0.294 - 2.46 ] and$$

$${b}_{m} = [ 000 0.02 ] .$$

Given that the array S₂=[0 1] represents the second set of position data for the chips on the target substrate, it is suggestible to calculate the optimal relative displacement to complete the final repair of the last vacancy. In other words, when S₂=[1 1] is met, it indicates that the repair or implantation of the chips is complete. The aforementioned formulas and coefficients are illustrative and do not limit the scope of this application.

Although the present invention is written with respect to specific embodiments and implementations, various changes and modifications may be suggested to a person having ordinary skill in the art. It is intended that the present disclosure encompasses such changes and modifications that fall within the scope of the appended claims.

What is claimed is:

1. A system for repairing vacancies on a substrate comprising:
a transfer apparatus configured to transfer at least one first chip from a first substrate to at least one vacancy on a second substrate;
an image recognition module configured to respectively inspect and obtain first position data of the at least one first chip on the first substrate and second position data of at least one second chip on the second substrate; and
a computation processing module configured to input the first position data and the second position data into a predictive machine model to obtain a relative displacement;
wherein the transfer apparatus generates a motion between the second substrate and the first substrate based on the relative displacement to perform a transfer of the at least one first chip.

2. The system according to claim 1, wherein the relative displacement is an optimal relative displacement which is obtained by adjusting parameters in the predictive machine model to minimize a loss value.

3. The system according to claim 2, wherein after the transfer of the at least one first chip, the transfer apparatus counts a number of remaining vacancies on the second substrate.

4. The system according to claim 3, wherein if the number of remaining vacancies is not zero, the first position data and the second position data are updated, and another optimal relative displacement is calculated for a next transfer of chips.

5. The system according to claim 1, wherein an architecture of the predictive machine model includes:
a repair platform simulator generating first virtual position data and second virtual position data;
a platform displacement prediction model having inputs of the first virtual position data and the second virtual position data to calculate a plurality of scores of platform displacement, obtaining an optimal virtual relative displacement corresponding to a highest score which is selected from the scores, providing the optimal virtual relative displacement to the repair platform simulator to generate simulated movement and simulate a transfer of chips, and output a transfer count; and
a loss function model updating parameters of the platform displacement prediction model based on the transfer count and the scores of the platform displacement.

6. The system according to claim 5, wherein the repair platform simulator comprises:
a virtual carrier platform generating a first simulated movement of a virtual first substrate based on the optimal relative displacement;
a virtual target platform generating a second simulated movement of a virtual second substrate based on the optimal virtual relative displacement; and
a virtual laser source transferring at least one virtual chip on the virtual first substrate to at least one vacancy on the virtual second substrate.

7. The system according to claim 5, wherein the loss function model uses the plurality of scores of platform displacement, the transfer count, and a plurality of scores of platform displacement from a previous round to calculate loss values.

8. The system according to claim 7, wherein the platform displacement prediction model calculates a virtual relative displacement for a next round based on the updated parameters.

9. The system according to claim 8, wherein when the loss value is less than a threshold, the platform displacement prediction model stops processes of training and learning.

10. The system according to claim 1, wherein the image recognition module includes an image capture unit and a judgment unit, which separately inspect distribution and status of the at least one first chip on the first substrate and the at least one second chip on the second substrate to obtain the first position data and the second position data.

11. A method for repairing vacancies on a substrate comprising:
inspecting a first substrate to obtain a first position data for at least one first chip and inspecting a second substrate to obtain a second position data for at least one second chip;
inputting the first position data and the second position data into a predictive machine model to obtain a relative displacement;
generating a motion between the second substrate and the first substrate based on the relative displacement; and
transferring the at least one first chip to at least one vacancy on the second substrate.

12. The method according to claim 11, wherein the step of obtaining the relative displacement further comprises adjusting parameters of the predictive machine model to minimize a loss value, thereby obtaining an optimal relative displacement.

13. The method according to claim 12, further comprising calculating a number of remaining vacancies on the second substrate after a transfer of the at least one first chip is complete.

14. The method according to claim 13, wherein if the number of remaining vacancies is not zero, the first position data and the second position data are updated, and another optimal relative displacement is calculated for a next transfer of chips.

15. The method according to claim 11, wherein an architecture of the predictive machine model is generated by the following steps:
generating first virtual position data and second virtual position data;
inputting the first virtual position data and the second virtual position data to calculate a plurality of scores of platform displacement;
obtaining an optimal virtual relative displacement corresponding to a highest score which is selected from the scores;
using the optimal virtual relative displacement to simulate a motion between a virtual second substrate and a virtual first substrate and a transfer of chips, and output a transfer count; and
updating parameters of the predictive machine model based on the transfer count and the scores of the platform displacement.

16. The method according to claim 15, comprises:
generating a first simulated movement of the virtual first substrate based on the optimal relative displacement;
generating a second simulated movement of the virtual second substrate based on the optimal relative displacement; and
transferring at least one virtual chip on the virtual first substrate to at least one vacancy on the virtual second substrate.

17. The method according to claim 15, wherein the predictive machine model further comprises a loss function model which uses the plurality of scores of platform displacement, the transfer count, and a plurality of scores of platform displacement from a previous round to calculate loss values.

18. The method according to claim 16, further comprises: calculating a virtual relative displacement for a next round based on the updated parameters.

19. The method according to claim 18, wherein when the loss value is less than a threshold, the platform displacement prediction model stops processes of training and learning.

20. The method according to claim 18, wherein the first position data and the second position data respectively represent distribution and status of the at least one first chip on the first substrate and the at least one second chip on the second substrate.
